(19) United States
(12) Patent Application Publication
(10) Pub. No.: US 2008/0205899 A1
(43) Pub. Date: Aug. 28, 2008

(54) Optoelectronic Transmitting and Receiving Device

(75) Inventors: Christophe Kopp, Fontanil-Cornillon (FR); Bruno Mourey, Coublevie (FR); Philippe Grosse, Sassenage (FR)

Correspondence Address: OBLON, SPIVAK, MCCLELLAND MAIER & NEUSTADT, P.C., 1940 DUKE STREET, ALEXANDRIA, VA, 22314, US

(73) Assignee: COMMISSARIAT A L'ENERGIE ATOMIIQUE, Paris (FR)

(21) Appl. No.: 11/913,467

(22) PCT Filed: May 5, 2006
(86) PCT No.: PCT/FR06/50415

§ 371 Date: Nov. 2, 2007

(30) Foreign Application Priority Data
May 10, 2005 (FR) 05 51202

(51) Int. Cl. H04B 10/00; H01L 33/00; H01L 31/18

(52) U.S. Cl. 398/139; 438/25; 257/E33.077; 257/E31.095

(57) ABSTRACT

An optoelectronic transmitting and receiving device, including a pierced platform including at least one through hole for introduction of an optical fiber, a first optoelectronic element integral with the platform, arranged substantially facing the through hole and configured to emit or receive a first laser beam at a first wavelength, and at least one second optoelectronic element hybridized on the platform and arranged substantially facing the through hole. The first element is arranged between the platform and the second element, which is configured to receive or emit a second laser beam at a second wavelength, different than the first wavelength, passing through the first element.

### TECHNICAL FIELD

The present invention concerns the field of telecommunications and, more specifically, the field of components located at the optical/electrical interfaces of telecommunication networks, such as an optoelectronic transmitting and receiving device, generally known as a “transceiver”, and a method for its manufacture. Said device is particularly suitable for the transmission and reception of data in optical telecommunication networks.

### STATE OF THE PRIOR ART

The rapid progression of the performance of modems and xDSL (x Digital Subscriber Line) systems clearly shows that before 2010, technologies on copper will reach the maximum of their limits. Only PON (Passive Optical Network) technology is capable of meeting a vast demand at the lowest market price. In this type of network, components located at the optical/electrical interfaces play the role of transmitter and receiver, and carry out the conversion of optical signals into electrical signals, and vice versa. These transmitting and receiving devices are generally known as “transceivers”.

In PON networks, two types of transceivers are currently used:
duplexers, which are typically composed of an optoelectronic circuit connected to an optical fibre through which transits descending optical signals, in other words the signals coming from a network towards the transceiver, and ascending optical signals, in other words signals emitted by the transceiver towards the network. Descending optical signals generally have a wavelength different to that of ascending optical signals. For a duplexer, these descending and ascending optical signals transport information and/or vocal communication data. FIG. 1A represents an example of duplexer 1. An optical fibre 2 has a first end connected to the duplexer 1 and a second end connected to a PON network 3. In FIG. 1A, a descending optical signal λd1 and an ascending optical signal λa, each transporting information and/or vocal communication data, are conveyed by the optical fibre 2.
triplexers, which are devices very analogous to duplexers. Compared to duplexers, they generate in general an additional descending path allocated to the transport of video information. FIG. 1B represents an example of triplexer 4. An optical fibre 2 has a first end connected to the triplexer 4 and a second end connected to a PON network 3. In FIG. 1B, the optical fibre 2 transmits a descending optical signal λd1 of information and/or vocal communication data, a descending optical signal λd2 of video information and an ascending optical signal λa of information and/or vocal communication data.

In optical transmission, the transmitter component used in a transceiver is generally one of the following two types: EEL (Edge Emitting Laser) or VCSEL (Vertical Cavity Surface Emitting Laser). FIG. 2A represents an EEL 5 emitting a laser beam 6 by a side 7. FIG. 2B represents a VCSEL 8 that emits a laser beam 6 by a surface 9.

FIG. 2C is a detailed representation of the VCSEL 8. The VCSEL 8 comprises a vertical laser cavity 23. An active medium 20, based on semi-conductor materials with multiple quantum wells is located in this laser cavity 23. The active medium 20 is a periodic arrangement of layers of semi-conductor material with a wide forbidden band width (for example aluminium and gallium arsenide GaAlAs or aluminium arsenide AlAs) and layers of semi-conductor material with small forbidden band width (for example gallium arsenide GaAs). In FIG. 2C, the thickness of the active medium 20 is very low since it only contains several quantum wells. When a thin film of semi-conductor material with small forbidden band width (typically around 10 nanometres) is arranged between two layers of material with a wider forbidden band, the electrons and the holes of the material with small forbidden band width are confined in single direction potential wells. The movement of an electron in a quantum well, created in the conduction band (height ΔEc), is quantified in discrete permitted energy states E₁, E₂, E₃, etc. In the same way, the movement of a hole in a quantum well, created in the valence band (height ΔEv) is quantified in discrete permitted states, of energy E′₁, E′₂, E′₃, etc. When the thickness of the material with small forbidden band width varies, the energy states taken by the carriers also vary. The emission wavelength of structures with multiple quantum wells may therefore be adjusted through the choice of the nature and the thickness of the layers of semi-conductor material. The laser cavity 23 may be electrically pumped by means of electrons produced on either side of the structure. The VCSEL 8 further comprises a first Bragg mirror 21 and a second Bragg mirror 22, between which is arranged the active medium 20. These two Bragg mirrors 21, 22 are composed of successive thin films of semi-conductor materials. The Bragg mirrors 21, 22 may for example be formed based on aluminium arsenide (AlAs) and gallium arsenide (GaAs). Each monolithic mirror 21, 22, may be formed, at a wavelength λ, by employing a stack of layers i and j, respectively of material with high and low optical indices nᵢⱼ, of thickness corresponding to a dephasing equal to around λ/4. However the mirrors may also be formed based on dielectric materials such as silicon dioxide (SiO₂), titanium dioxide(TiO₂) or even hafnium dioxide (HfO₂). The axis of propagation of a laser beam 6, which is also the axis of the laser cavity 23, is substantially perpendicular to the plane defined by the layers of semi-conductor of the Bragg mirrors 21, 22 and of the active medium 20. The laser beam 6 is emitted from a front face 24 of the VSCEL 8. Typically, a laser beam emitted by a traditional VCSEL is circular, of diameter equal to around 20 micrometers, has a divergence of around 7°, and a spectral width of several tenths of nanometres (for example 0.3 nanometres). For ranges of wavelengths around 1310 nanometres or 1550 nanometres, the VCSEL 8 emits light towards the front face 24 but also towards a rear face 25, opposite to the front face 24, since the substrate used is generally transparent to these wavelengths, and the Bragg mirrors 21, 22 that form the vertical laser cavity 23 do not have a reflectivity rate of 100%. Typically, in a conventional VCSEL, the Bragg mirror located on the side of a front face of the VCSEL has a lower reflectivity rate than the mirror located on the side of a rear face of the VCSEL, in order to determine the emission direction. For the VCSEL 8 of FIG. 2C, the reflectivity rate for the first Bragg mirror 21 located on the side of the rear face 25 is around 99.8% and around 99% for the second Bragg mirror 22 located on the side of the front face 24.

A VCSEL based on AlGaAs can emit several milliwatts at a wavelength substantially between 800 and 850 nanometres, in a beam of circular section of diameter equal to around 8 micrometers. A VCSEL based on InGaAs emits a power of around 50 milliwatts at around 980 nanometres, for a circular beam of diameter equal to around 30 micrometers. The powers of these two examples correspond to continuous emission powers. The diameters of the beams emitted by VCSEL vary from several micrometers up to around 150 micrometers. Finally, the structure of a VCSEL lends itself easily to the manufacture of networks of one- or two-dimensional VCSEL.

The receiving component used in a transceiver is generally a photodiode type photodetector based on a material such as gallium arsenide (GaAs), gallium and indium arsenide (InGaAs) or indium phosphide (InP).

Duplexers and triplexers are multiplexers presently using one of the following two multiplexing techniques: multiplexing in free beam with beam splitter, or multiplexing in planar guided optics.

Multiplexing in free beam with beam splitter is the most basic technique. A transceiver 10 using this multiplexing technique is shown in FIG. 3A. It comprises an EEL or VSCEL type laser emitter 11, a photodetector 12 such as a photodiode and a beam splitter 13. The beam splitter 13 is used to transmit an ascending optical signal λa from the transmitter 11 towards the optical fibre 2 and to transmit a descending optical signal λd1 from the optical fibre 2 to the photodetector 12. Passive optical components, not represented in FIG. 3A, such as lenses, are generally inserted at different levels in order to improve the shaping of the optical signals λa and λd1. One of the advantages of this type of multiplexing is the low cost necessary for forming such a transceiver 10 since each unit element of said transceiver 10 is very simple. Another advantage of multiplexing in free beam with beam splitter 13 is the high coupling rate between the transmitter 11 and the optical fibre 2, and between the receiver 12 and the optical fibre 2. These high coupling rates are obtained by means of passive optical components inserted in the transceiver 10.

Nevertheless, this solution has its disadvantages. The insertion of passive optical components in a transceiver multiplexing in free beam with beam splitter is complex. It necessitates an awkward step of alignment of these passive optical components between each other and with the other elements of the transceiver. This alignment is generally carried out actively, in other words by electrically connecting the transceiver and by making it emit a laser beam, which implies a unitary and sequential treatment of each of the transceivers while they are being assembled. In addition, the increase in the number of optical components in the transceiver increases the sensitivity to misalignments that occur during the ageing of the transceiver. Another major disadvantage of this system is the considerable size. Due to its very principle, this transceiver architecture is particularly voluminous given the large dimensions of the unit components used, these dimensions being necessary for their handling.

A transceiver 14 using multiplexing in planar guided optics is represented in FIG. 3B. This transceiver 14 comprises a platform 15 stemming from planar guided optics technology. This platform comprises optical guides 16 used for the wavelength multiplexing and demultiplexing of optical signals. It further comprises a source laser 17 for the emission of ascending optical signals, a photodetector 18 for the reception of descending optical signals, and an integrated optical separator 19. This platform 15 could also accommodate other components such as a thermistor, a monitoring photodetector or even a current amplifier. This platform 15 in guided optics technology may be manufactured according to one of three main current technologies for forming optical guides:
optical guide on glass by the ion exchange technique. This technique enables the generation of optical guides buried by ion exchange. A glass substrate comprising sodium ions, for example silicate or borosilicate, is firstly immersed in a bath of molten silver salts in order to make the silver ions penetrate into the substrate, thereby generating a guide core on the surface. Secondly, the substrate undergoes an electrical field assisted annealing in order to make the core of the guide migrate in depth in relation to the surface of the substrate and form the geometry of the section of the core of the guide, generally circular.
Optical guide in doped silica on silicon formed on the surface. This technique enables the generation of optical guides by a series of depositions and micro-structurings. Firstly, the core of the guide of square section is formed on the surface of a substrate in silicon coated with a layer of silica playing the role of optical cladding. Secondly, the core of the guide thereby formed is coated with a layer of silica in order to obtain a suitable refractive index sheath around the guide. The core of the guide is formed by photolithography and etching techniques stemming from microelectronics in a material of phosphorous, boron or germanium doped silica type.
Optical guide on silica on silicon generated by local ion implantation. This technique enables the generation of optical guides buried in a layer of silica on the surface of a substrate in silicon. The cores of the guides are obtained by implantation of titanium ions. Controlling the implantation energy makes it possible to control the implantation depth and thereby the geometry of the guide.

Compared to multiplexing in free beam with beam splitter, multiplexing in planar guided optics makes it possible to integrate more electronic functions in the transceiver 14, such as for example a current amplifier or a thermistor, and to minimise the alignment steps, given that the separation function is integrated in the platform 15 in planar guided optics. On the other hand, this solution has several technical disadvantages:
the laser emitters used on this type of platform are generally EEL that have a geometry well suited to this planer technology thanks to their edge laser emission. On the other hand, the elliptic shape of the beam emitted by this type of source is in general particularly unsuited to a high coupling in optical guides. The envisaged solutions, such as mode adaptation at the level of the guide or through the use of an optic coupling system, complicates the architecture and makes the alignment step awkward by increasing the sensitivity of the system to positioning errors.
The small size mode in the optical guides (diameter of around several micrometers) compared to that of the optical fibre (diameter between around 10 micrometers and several tens of micrometers) necessitates the use of a fibre/guide coupling optic system that further complicates the architecture and makes the alignment step awkward by increasing the sensitivity of the system to positioning errors.

In order to resolve these coupling problems, patent application US 2003/0098511 proposes an optical circuit hybridized on a pierced platform, forming an optical circuit/optical fibre passive coupling system, and thereby replacing the use of an optical coupling system such as a device for multiplexing in free beam with beam splitter or in planar guided optics. Here, and in the remainder of this document, “hybridized” is taken to mean a connection that is both mechanical and electrical. Typically, if said optical circuit is a transmitter, said transmitter can be a VCSEL, since the geometry of the beam emitted by a VCSEL is naturally easier to couple in an optical fibre. Indeed, the geometry of the beam emitted by a VCSEL is circular and symmetrical, and not rectangular, and does not have astigmatism and ellipticity as in laser diodes. FIG. 3C represents an architecture of an optical circuit/optical fibre passive coupling system 26 as disclosed in the abovementioned patent application. This system 26 comprises an optical circuit, here a VCSEL 8, emitting a laser beam 6, an optical fibre 2, and a pierced platform 27. This architecture uses in particular the precision of microelectronic machining methods for the platform 27, which may be in silicon and formed for example by photolithography or by deep dry etching, and the precision of positioning of the VCSEL 8 hybridized by flip-chip connection technology, with microbeads 28 of a fusible material. Typically, such a system enables a lateral precision for centring the VCSEL 8 compared to the core of the optical fibre 2 less than around one or two micrometers.

It is therefore worthwhile using a VCSEL in this configuration for a transceiver in order to benefit from the additional electronic functionalities enabled by the platform, and forming a passive coupling of the VCSEL with the optical fibre. However, this type of architecture, which is efficient for the VCSEL/fibre coupling, may complicate the formation of the fibre/photodetector coupling function, which has to be formed on a separate device. Indeed, traditional solutions that use an optical system for collecting the laser beam emitted by the VCSEL 8, between the VCSEL 8 and the optical fibre 2 with for example a collection plate, cannot be envisaged given the limited available volume. This solution therefore makes it necessary to have a transmitting device and a receiving device independent of each other, each using a different optical fibre.

Patent application FR 2 807 168 also describes a device and a passive method for aligning optical fibres and optoelectronic components using the technique of positioning by microbeads. However this solution has the same disadvantages as the device proposed in patent application US 2003/0098511.

### DISCLOSURE OF THE INVENTION

The aim of the present invention is to propose an optoelectronic transmitting and receiving device that does not have the disadvantages mentioned above, in other words a transmitting and receiving device benefiting both from a platform making it possible to accommodate additional electronic functions, in which the transmitter/fibre and fibre/photodetector coupling systems are efficient and suitable for a passive assembly, and which is compact.

To attain these aims, the present invention proposes an optoelectronic transmitting and receiving device, intended to cooperate with an optical fibre, comprising:
a pierced platform, equipped with at least one through hole into which the optical fibre must be introduced, and
a first optoelectronic element integral with the platform, arranged substantially facing the hole and intended to emit or receive a first laser beam at a first wavelength that has to be conveyed by the optical fibre,

and comprising at least one second optoelectronic element hybridized on the platform and arranged substantially facing the hole, the first optoelectronic element being arranged between the platform and the second optoelectronic element, which is intended to receive or emit a second laser beam at a second wavelength, different to the first wavelength, passing through the first optoelectronic element and which has to be conveyed by the optical fibre.

Thus, instead of forming a bulky device for multiplexing in free beam with beam splitter and necessitating a complex alignment, or a device for multiplexing in planar guided optics in which the implementation of the coupling is complex, or finally an optical circuit hybridized on a pierced platform, forming a passive coupling system of an optical circuit with an optical fibre but necessitating two optical fibres to form the emission and the reception, an optoelectronic transmitting and receiving device is formed comprising two superimposed optoelectronic elements, thereby forming the transmitter/fibre and fibre/photodetector coupling passively on a platform, which makes it possible to integrate additional electronic functions, the whole requiring a minimum of space.

In addition, since the second optoelectronic element is hybridized directly on the platform, a direct electrical contact is made between the second optoelectronic element and the platform, without going through the first optoelectronic element. The first optoelectronic element therefore does not have to be produced in double face technology, thereby simplifying the technological manufacture of this element compared to the devices of the prior art comprising a second optoelectronic element hybridized on a first optoelectronic element.

The present invention further proposes an optoelectronic transmitting and receiving device, comprising:
a pierced platform, equipped with at least one through hole for the introduction of an optical fibre,
a first optoelectronic element integral with the platform, arranged substantially facing the hole and intended to emit or receive a first laser beam at a first wavelength,
at least one second optoelectronic element hybridized on the platform and arranged substantially facing the hole, the first optoelectronic element being arranged between the platform and the second optoelectronic element, which is intended to receive or emit a second laser beam at a second wavelength, different to the first wavelength, passing through the first optoelectronic element.

It is preferable that the first optoelectronic element is transparent or quasi-transparent to the second wavelength of the second laser beam received or emitted by the second optoelectronic element, so that this second laser beam arrives with the least power losses in the second optoelectronic element or an optical fibre.

The first optoelectronic element may be a laser emitter, such as a VCSEL.

The second optoelectronic element may be a photodetector, such as a photodiode.

In another embodiment, the first optoelectronic element may be a photodetector, such as a photodiode.

In this case, the second optoelectronic element may be a laser emitter, such as a VCSEL.

The VCSEL may comprise a laser beam emission surface oriented facing the hole and a microlens integrated on this emission surface.

The first optoelectronic element may be hybridized on the platform.

In this case, it is preferable that the hybridization of the first optoelectronic element on the platform is carried out with a connection by microbeads. These microbeads assure the passive coupling of the first optoelectronic element with the optical fibre and also the mechanical fixing and an electrical and thermal contact between this first element and the platform.

It is then preferable that the microbeads associated with the first optoelectronic element are based on a fusible material.

It may be envisaged that the fusible material is an alloy based on gold and tin, tin and lead, or a pure or almost pure metal based on tin or indium.

It is preferable that the hybridization of the second optoelectronic element is carried out with a connection by microbeads.

In this case, it is preferable that the microbeads associated with the second optoelectronic element are based on a fusible material.

It may then be envisaged that the fusible material is an alloy based on gold and tin, tin and lead, or a pure or almost pure metal based on tin or indium.

All of the microbeads associated with the second optoelectronic element may have substantially a same diameter.

In another case, the microbeads associated with the second optoelectronic element, may not all have substantially a same diameter.

A filter may be inserted between the first and the second optoelectronic element.

This filter may be arranged on one face of the second optoelectronic element that is located on the side of the first optoelectronic element.

The platform may be based on silicon.

The present invention further concerns a method for producing a transmitting and receiving device, intended to cooperate with an optical fibre, comprising the following steps:

a) solidarisation of a first optoelectronic element with a pierced platform, equipped with at least one through hole in which the optical fibre has to be introduced, the first optoelectronic element being arranged substantially facing the hole,

b) solidarisation of a second optoelectronic element with the platform, the second optoelectronic element comprising one face arranged substantially facing the hole, carried out according to the following steps:
formation of microbeads based on a fusible material on the face of the second optoelectronic element, said face being intended to be on the side of the hole,
hybridization of the second optoelectronic element on the platform by the microbeads,

the first optoelectronic element being arranged between the platform and the second optoelectronic element.

The present invention further concerns a method of forming a transmitting and receiving device, comprising the following steps:

a) solidarisation of a first optoelectronic element with a pierced platform, equipped with at least one through hole for the introduction of an optical fibre, the first optoelectronic element being arranged substantially facing the hole,

b) solidarisation of a second optoelectronic element with the platform, the second optoelectronic element comprising one face arranged substantially facing the hole, carried out according to the following steps:
formation of microbeads based on a fusible material on the face of the second optoelectronic element, said face being intended to be on the side of the hole,
hybridization of the second optoelectronic element on the platform by the microbeads,

the first optoelectronic element being arranged between the platform and the second optoelectronic element.

The method, subject of the present invention, may comprise before the step a) a step of piercing of the platform, thereby forming the hole.

The solidarisation of the first optoelectronic element with the platform may be carried out according to the following steps:
formation of microbeads based on a fusible material on one face of the first optoelectronic element, said face being intended to be facing the hole or the optical fibre,
hybridization of the first optoelectronic element on the platform by the microbeads.

It may be envisaged that the method, subject of the present invention, comprises an additional step consisting in inserting, between the first optoelectronic element and the second optoelectronic element, a filter.

It may also be envisaged that the method, subject of the present invention, comprises an additional step consisting in arranging a filter on said face of the second optoelectronic element.

### BRIEF DESCRIPTION OF DRAWINGS

The present invention may best be understood by reference to the following description of embodiments provided as an indication only and in no way limitative and by referring to the accompanying drawings in which:

FIG. 1A, already described, is an example of duplexer of the prior art,

FIG. 1B, already described, is an example of triplexer of the prior art,

FIG. 2A, already described, is an example of EEL of the prior art,

FIG. 2B, already described, is an example of VCSEL of the prior art,

FIG. 2C, already described, is an example of VCSEL of the prior art,

FIG. 3A, already described, is an example of transceiver multiplexing in free beam with beam splitter of the prior art,

FIG. 3B, already described, is an example of transceiver multiplexing in planar guided optics of the prior art,

FIG. 3C, already described, is an example of optical circuit/optical fibre passive coupling device of the prior art,

FIG. 4 is a diagram of an optoelectronic transmitting and receiving device, subject of the present invention, according to a first embodiment,

FIG. 5 is a cross section of a VCSEL used in an optoelectronic transmitting and receiving device, subject of the present invention,

FIG. 6A represents a reflectance curve of a standard Bragg mirror,

FIG. 6B represents a reflectance curve of a modified Bragg mirror,

FIG. 7A is a diagram of an optoelectronic transmitting and receiving device, subject of the present invention, according to a variant of the first embodiment,

FIG. 7B is a diagram of an optoelectronic transmitting and receiving device, subject of the present invention, according to another variant of the first embodiment,

FIG. 8 is a diagram of an optoelectronic transmitting and receiving device, subject of the present invention, according to a second embodiment,

FIG. 9 is a diagram of an optoelectronic transmitting and receiving device, subject of the present invention, according to a third embodiment,

FIG. 10 is a diagram of an optoelectronic transmitting and receiving device,

FIGS. 11a to 11k represent the steps of forming microbeads on an optoelectronic element, carried out while producing an optoelectronic transmitting and receiving device, subject of the present invention,

FIG. 12 represents the steps of a hybridization of an optoelectronic element on a platform, carried out during a method of producing an optoelectronic transmitting and receiving device, subject of the present invention.

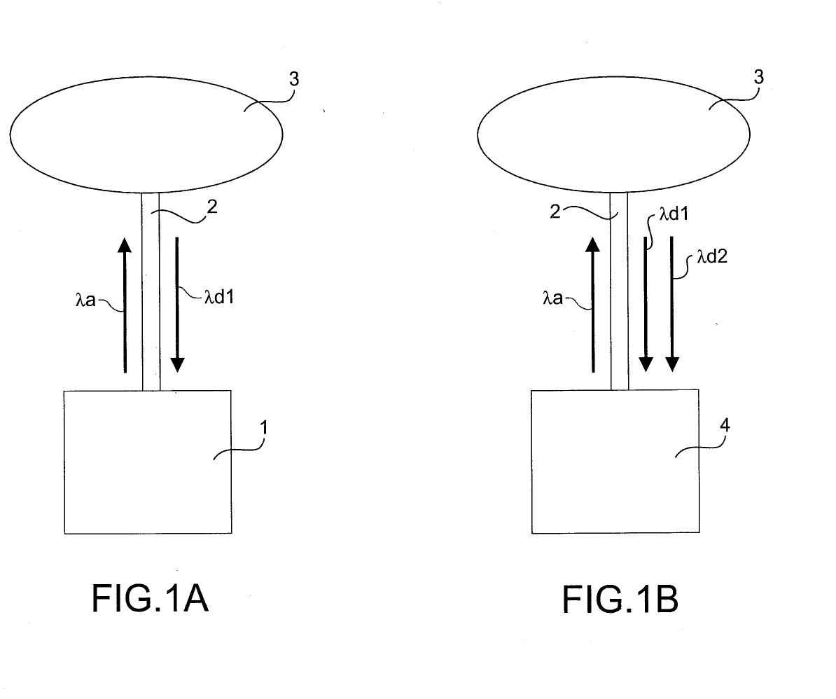

In the description that follows, identical, similar or equivalent parts of the various figures bear the same numerical references so as to simplify passing from one figure to the next.

The various parts in the figures are not necessarily shown at a uniform scale in order to make the figures clearer.

### DETAILED DESCRIPTION OF SPECIFIC EMBODIMENTS

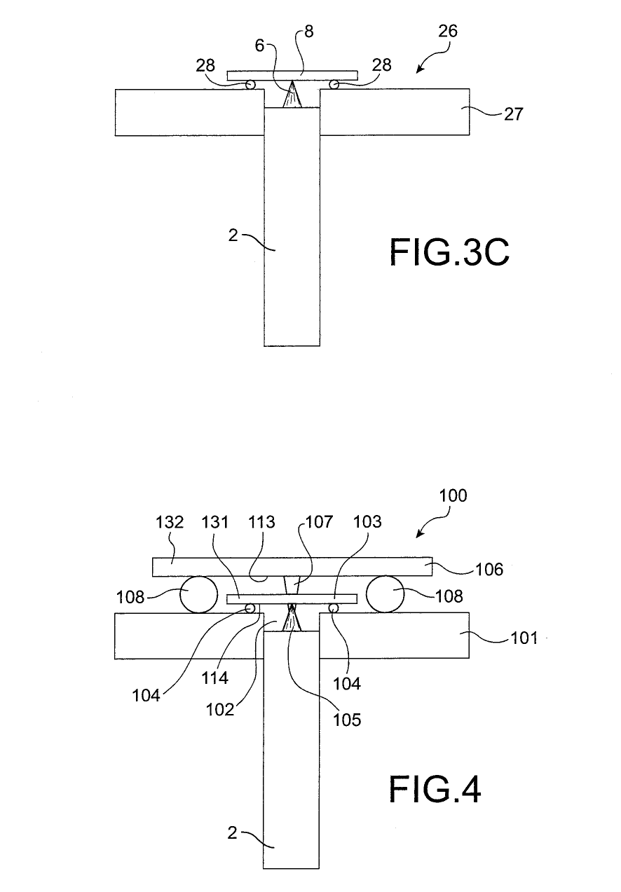

Reference is made to FIG. 4, which shows a cross section of an optoelectronic transmitting and receiving device 100, subject of the present invention, according to a first embodiment. This device 100 comprises a platform 101. In this embodiment, the platform 101 is formed based on silicon. The platform 101 is pierced and is equipped with at least one through hole 102. In FIG. 4, this hole 102 has a section substantially constant along one thickness of the platform. Indeed, in this first embodiment, the hole 102 has a substantially cylindrical shape, but it could have a different shape.

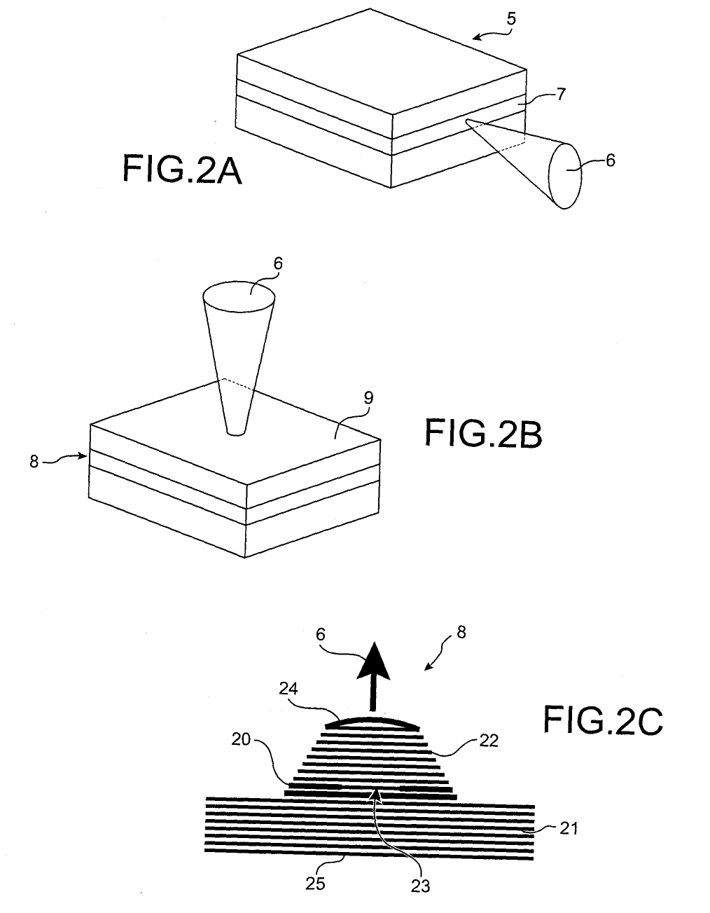

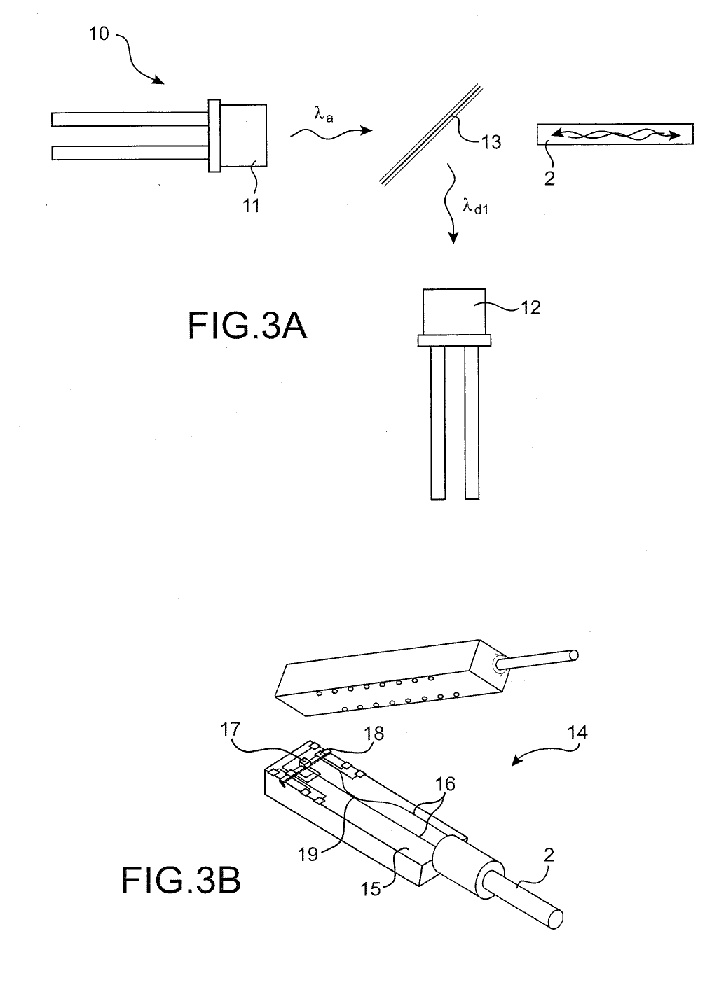

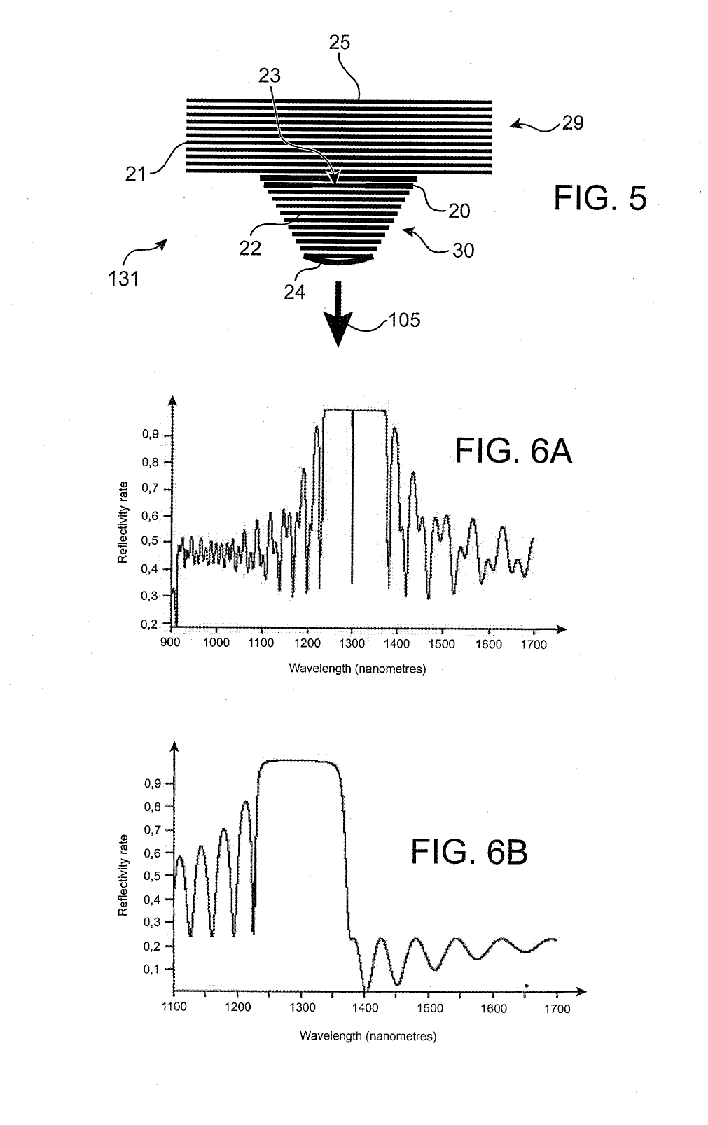

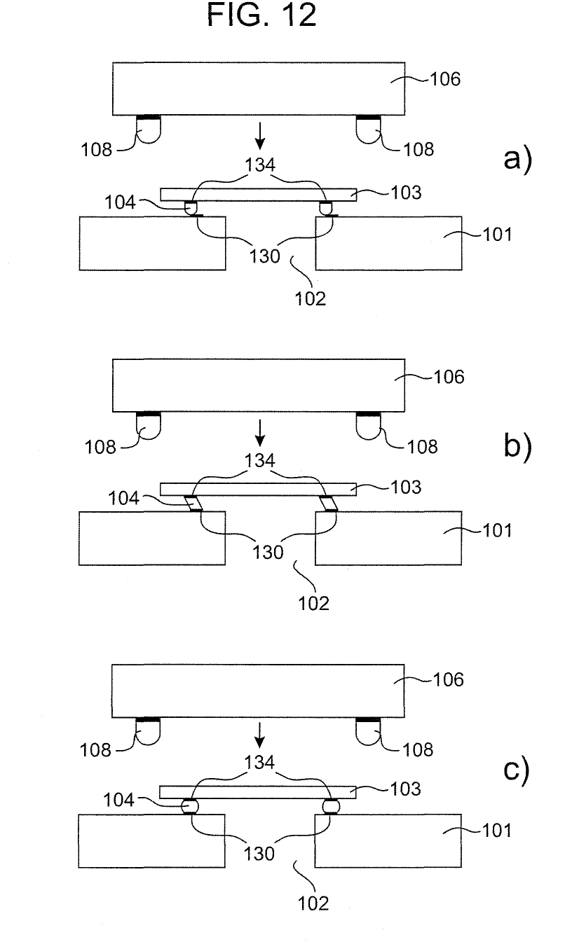

The device 100 further comprises a first optoelectronic element 103, integral with the platform 101 and arranged substantially facing the hole 102. In FIG. 4, this first optoelectronic element 103 is centred above the hole 102. In this first embodiment, the first optoelectronic element 103 is hybridized on the platform 101, in other words it is fixed both mechanically and electrically onto the platform 101. In this embodiment, the hybridization of the first optoelectronic element 103 is carried out with a connection by microbeads 104. Said microbeads 104 are in a fusible material. Apart from their role of mechanical and electrical connection, they also have a thermal role since they enable the heat due to the operation of the first optoelectronic element 103 to be dissipated. Several tens of microbeads 104 are used to carry out the hybridization. Said microbeads 104 are arranged substantially on the periphery on one face 114 of the first optoelectronic element 103. In FIG. 4, only two microbeads 104 are visible. The fusible material may for example be an alloy based on gold and tin, an alloy based on tin and lead, or a pure or almost pure metal based on tin or indium. In this first embodiment, they all have substantially a same diameter. Said microbeads 104 are in contact with the first optoelectronic element 103 and with the platform 101 through metallic contacts 130, 134, not shown in FIG. 4 but visible in FIG. 12. This first optoelectronic element 103 emits or receives a first laser beam 105 at a first wavelength depending on its nature (transmitter or receiver). In the embodiment of FIG. 4, the first optoelectronic element 103 is a laser emitter, for example a VCSEL 131, which emits the first laser beam 105, as is illustrated in FIG. 5. This VCSEL 131 may comprise the same types of elements as those composing the VCSEL 8 illustrated in FIG. 2C, in other words comprising a laser cavity 23, an active medium 20 arranged between two mirrors 21, 22, a front face 24 and a rear face 25.

The device 100 is intended to cooperate with an optical fibre 2. When the device 100 is in operation, the optical fibre 2 is introduced into the hole 102 of the platform 101, as can be seen in FIG. 4. The optical fibre 2 makes it possible to convey the first laser beam 105 emitted by the VCSEL 131.

According to the present invention, the device 100 also comprises at least one second optoelectronic element 106. This second optoelectronic element 106 is also hybridized on the platform 101 and is also centred substantially above the hole 102. The second optoelectronic element 106 is arranged above the first optoelectronic element 103 so that this first optoelectronic element 103 is placed between the platform 101 and the second optoelectronic element 106. Given that the first optoelectronic element 103 is the transmitting element of the transmitting and receiving device 100, the second optoelectronic element 106 is therefore a receiving element of the device 100, so that the device 100 is both transmitter and receiver. For example, in FIG. 4, the second optoelectronic element 106 is a photodetector, such as a photodiode 132. In FIG. 4, the photodiode 132 receives a second laser beam 107 at a second wavelength, different to the first wavelength of the first laser beam 105, conveyed by the optical fibre 2, which goes through the VCSEL 131 before reaching the photodiode 132. In this embodiment, as for the first optoelectronic element 103, the second optoelectronic element 106 is hybridized on the platform 101 with a connection by microbeads 108. As for the microbeads 104 associated with the first optoelectronic element 103, the microbeads 108 associated with the second optoelectronic element 106 are formed based on a fusible material. The fusible material of these microbeads 108 may be one of those enumerated above in the description for the fusible material of the microbeads 104. In this embodiment, the microbeads 108 associated with the second optoelectronic element 106 also all have substantially a same diameter, which enables the two optoelectronic elements 103, 106 to be substantially parallel to each other, and are in contact with the second optoelectronic element and with the platform 101 through electrical contacts, not shown in FIG. 4. These microbeads 108 associated with the second optoelectronic element 106 are arranged substantially at the periphery on one face 113 of the second optoelectronic element 106.

Thus hybridized, the first optoelectronic element 103 and the second optoelectronic element 106 are passively coupled with the optical fibre 2, the alignment being achieved by the positioning precision of the optoelectronic elements 103, 106 that the microbeads 104, 108 offer.

The second laser beam 107 from the optical fibre 2 firstly passes through the VCSEL 131 before reaching the photodiode 132. Here therefore it is the VCSEL 131 that is transparent or quasi-transparent to the second wavelength so that the second laser beam 107 arrives with sufficient power in the photodiode 132. In order to have a VCSEL 131 as transparent as possible to the second wavelength, therefore to maximise the transmission of this second laser beam 107 through the VCSEL 131, two parameters of the VCSEL 131 may be taken into consideration:
the minimisation of the surfaces of the zones of VCSEL 131, which are absorbative or reflective to the second laser beam 107 received, such as for example the metallic contacts 130, 134 or the mirrors 21, 22 of the laser cavity 23,
the maximisation of the transmission of the VCSEL 131 at the second wavelength.

These two parameters may be envisaged in an individual or combined manner.

Indeed, the minimisation of the surfaces of the zones of the VCSEL 131 that are absorbative or reflective to the second laser beam 107 received is relatively awkward to implement since the geometry of the laser cavity 23 of the VCSEL 131 has a direct influence on the first laser beam 105 emitted by the VCSEL 131. For example, laterally, a too small laser cavity 23 would make the first laser beam 105 emitted unsuited to an efficient passive coupling with the optical fibre 2.

The maximisation of the transmission of the VCSEL 131 at the second wavelength is easier to implement. However, a further aim is to protect the photodiode 132 from parasite laser beams that may be emitted by the VCSEL 131 by its rear face 25. To do this, it is arranged that the mirrors 21, 22 of the laser cavity 23 are highly reflective to the first wavelength and highly transmissive to the second wavelength. As has been seen previously, the two mirrors 21, 22 are generally Bragg mirrors. Each of the mirrors 21, 22 is typically formed of a stack 29, 30, visible in FIG. 5, alternating two materials with different refractive indices, for example aluminium arsenide (AlAs) and gallium arsenide (GaAs), and of thickness corresponding to a dephasing of around λ/4 with λ an emission wavelength of the VCSEL 131, here the first wavelength. Therefore, to increase the reflectivity to the first wavelength, the aim is to modify slightly the structure of one or several Bragg mirrors 21, 22 of the VCSEL 131 by increasing the number of layers of different materials of one or several stacks 29, 30. This modification makes it possible to obtain a VCSEL 131 with a “transmission window” at a given wavelength, in other words a VCSEL 131 transparent or quasi-transparent to the second wavelength but highly reflective to the first wavelength. This technique is already used for optically pumped VCSEL. For example, VCSEL exist having a Bragg mirror highly reflective to a wavelength of around 1300 nanometres, emission wavelength of the VCSEL, and having a transmission range around 980 nanometres, wavelength of a pump beam that passes through the mirror and then excites the quantum wells of the laser cavity of the VCSEL.

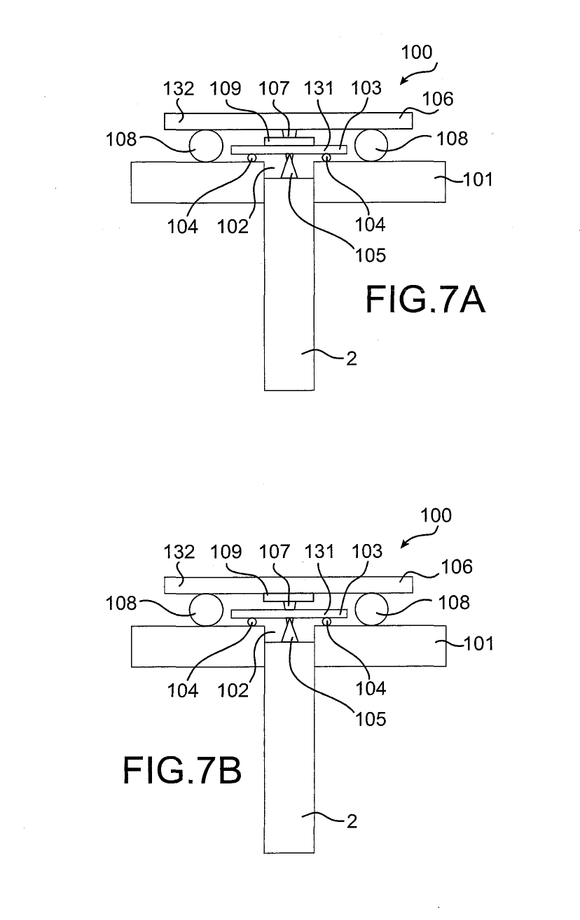

FIG. 6A represents a reflectance curve of a Bragg mirror generally used in a standard VCSEL. It may be seen in this FIG. 6A that the spectral reflectance curve of the Bragg mirror is of the band pass type centred around the wavelength of 1300 nanometres, emission wavelength of this VCSEL standard. FIG. 6B represents a reflectance curve of a Bragg mirror modified as is explained above. It may be seen on this curve that the reflection at around 1300 nanometres is respected and that moreover, it makes it possible to obtain an appreciable transmission gain at around 1500 nanometres, said gain being greater than around 80%. This mirror has been formed with a stack of 25 layers of AlAs and GaAs, the layers of AlAs having a thickness of 55.84 nanometres and the layers of GaAs having a thickness of 95.22 nanometres except for the layer of GaAs which is located at one end of the mirror, which has a thickness of 47.61 nanometres.

A second solution to obtain the maximisation of the transmission of the VCSEL 131 at the second wavelength is to replace one or both Bragg mirrors 21, 22 by mirrors known as “dichroic mirrors”. These mirrors are formed using the same techniques as Bragg mirrors but the thickness of each layer is optimised so as to obtain overall a high-pass or low-pass type reflectivity. It is thereby possible to maximise the reflectivity of the mirror to the first wavelength and to minimise its reflectivity to another wavelength. However, this type of stack is awkward to form since each layer has a different thickness and it is important to perfectly control the deposition speeds. This type of stack is a lot less tolerant to small errors of thickness than a conventional Bragg mirror.

In our embodiment, the VCSEL 131 represented in detail in FIG. 5 comprises the mirror 21, manufactured with 30 bi-layers of GaAs and of AlAs. The layers of GaAs of index n_{GaAs}=3.413 have a thickness of E_{GaAs}=95.22 nanometres and layers of AlAs of index n_{AlAs}=2.9102 have a thickness of E_{AlAs}=111.68 nanometres. The VCSEL 131 comprises the laser cavity 23 of optic length λ and in which the active medium has a thickness E_{milieuactif}=380.9 nanometres for a laser cavity 23 based on GaAs. Finally, the VCSEL 131 comprises the mirror 22, manufactured with 25 bi-layers of GaAs and of AlAs identical to those of the mirror 21.

Other examples of structures of vertical cavity semi-conductor laser are given in the document “Surface emitting semiconductor laser and Arrays”, of K. Iga et al., pages 87 to 117, Academic Press, San Diego, 1993. An example of such a structure comprises a p-doped substrate of InP, on which is formed a p-doped layer of InAlAs of 0.4 micrometers thickness. On this layer is formed the multiple quantum well structure, involving 10 alternations of layers of InGaAs of 9 nanometres thickness and of InAlAs of 20 nanometres thickness. Finally, the assembly is coated with an n-doped layer of InAlAs of 0.3 micrometers thickness.

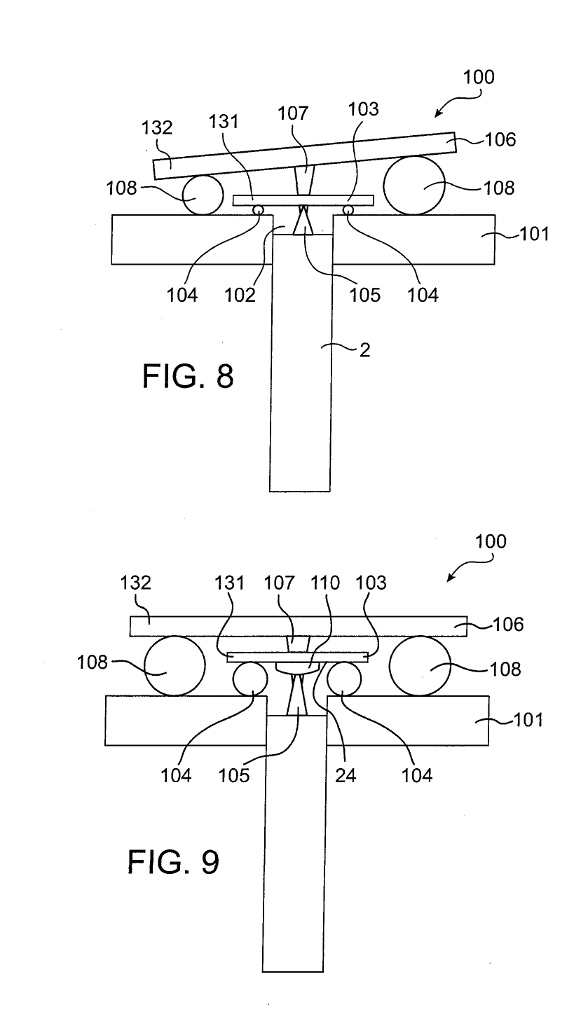

In an alternative embodiment, to protect the photodiode 132 from parasite laser beams that may be emitted by the VCSEL 131 by its rear face 25, a filter 109 is inserted between the first 103 and the second optoelectronic element 106, in other words in this variant of the first embodiment, between the VCSEL 131 and the photodiode 132, as may be seen in FIG. 7A. This filter 109 may for example be formed in the same way as a Bragg mirror, as explained previously. The filter 109 may also be arranged on the face 113 of the second optoelectronic element 106, this face 113 located on the side of the first optoelectronic element 103, as may be seen in FIG. 7B.

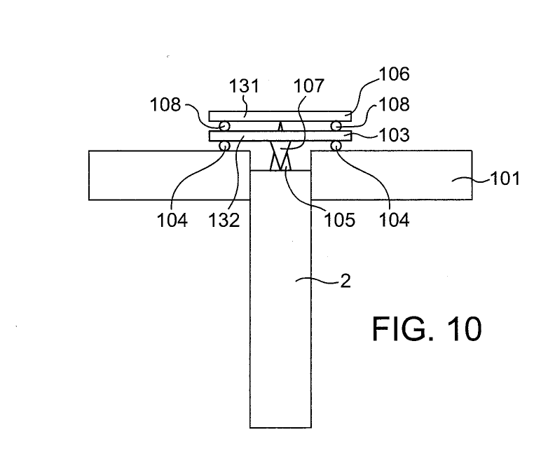

A further aim is that the power reflected from the second laser beam 107 towards the first optoelectronic element 103 is as low as possible, so as not to disrupt it. To do this, an optoelectronic transmitting and receiving device 100, subject of the present invention, according to a second embodiment, is shown in FIG. 8. This device 100 comprises, as in the device 100 according to the first embodiment, a pierced platform 101 similar to that of FIG. 4, a first and a second optoelectronic elements 103, 106 which are, as in the first embodiment, respectively a VCSEL 131 and a photodiode 132. As in the first embodiment, the VCSEL 131 is hybridized on the platform 101 by microbeads 104 based on a fusible material. The difference compared to FIG. 4 is that the photodiode 132 is hybridized on the platform 101 by microbeads 108 which do not all have substantially a same diameter. In this embodiment, the diameter of each of the microbeads 108 is chosen so that the two optoelectronic elements 103, 106 are no longer substantially parallel to each other. Thus, the second laser beam 107 from the optical fibre 2 no longer arrives perpendicularly on the photodiode 132. This inclination reduces the specular reflection towards the VCSEL 131 since if there is reflection, the second laser beam 107 is reflected next to the laser cavity 23 of the VCSEL 131. In this embodiment, it is also possible to insert the filter 109 between the first element 103 and the second element 106 or on the photodiode 132, as in FIGS. 7A and 7B. The technique of fixing one element to another with microbeads of different diameter is disclosed in the patent U.S. Pat. No. 5,119,240.

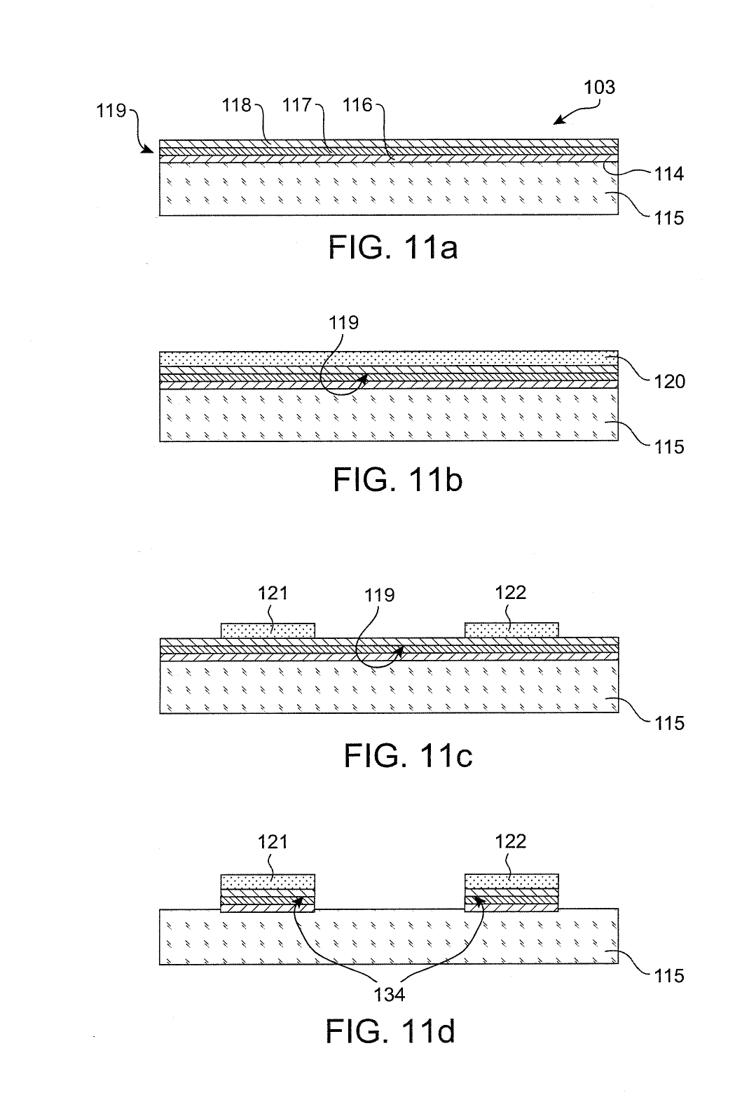

A third embodiment of an optoelectronic transmitting and receiving device 100 according to the present invention is represented in FIG. 9. As in the first embodiment, the device 100 comprises a pierced platform 101, a first element 103, which is a VCSEL 131 in this embodiment, hybridized on the platform 101 by microbeads 104, and a second element 106, which is here a photodiode 132, hybridized on the platform 101 by microbeads 108. The difference compared to the first embodiment is that the VCSEL 131 is equipped with a microlens 110 integrated on its emission surface 24. This microlens 110 makes it possible to increase the distance between the VCSEL 131 and an optical fibre 2. This greater distance between the VCSEL 131 and the optical fibre 2 assures a better coupling between these two elements. Consequently, the diameter of the microbeads 104 in this FIG. 9 is greater than that of the microbeads 104 of FIG. 4 for example.

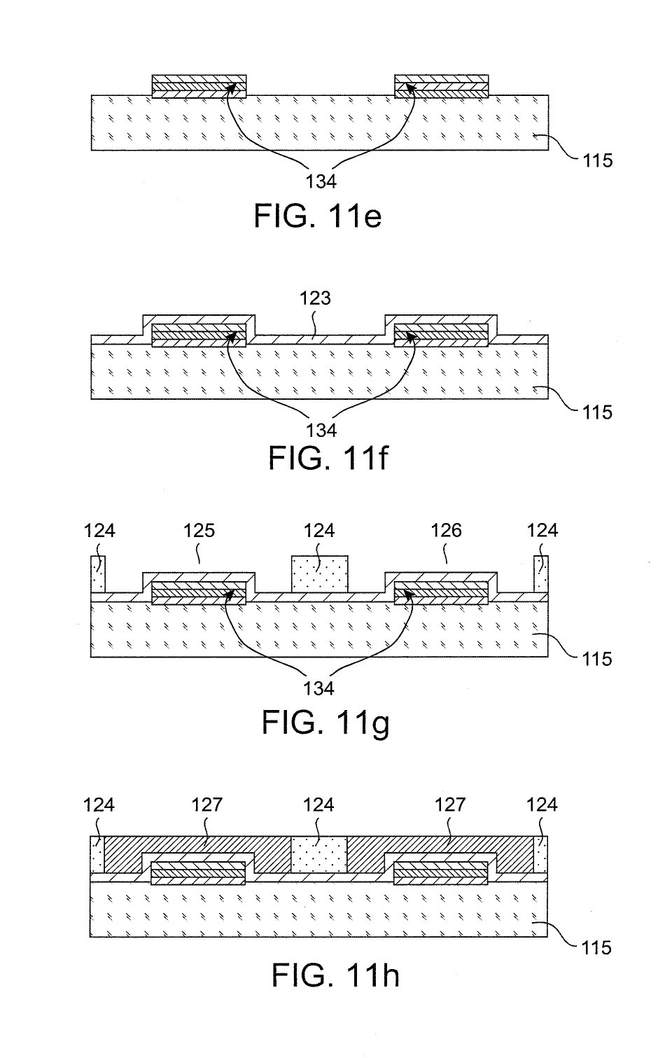

FIG. 10 represents an optoelectronic transmitting and receiving device. This device comprises a pierced platform 101 similar to that of the first embodiment, a first optoelectronic element 103 that is in this FIG. 10 a photodiode 132, as well as a second optoelectronic element 106 that is in this FIG. 10 a VCSEL 131. The photodiode 132 is hybridised on the platform 101 by microbeads 104. The second optoelectronic element 106, in other words the VCSEL 131, is made integral with the platform 101 by the intermediary of the first optoelectronic element 103. To do this, the VCSEL 131 is hybridized by microbeads 108 on the photodiode 132. Given that it is the photodiode 132 that is arranged between the VCSEL 131 and the optical fibre 2, the photodiode 132 is transparent to the first wavelength of the first laser beam 105 emitted by the VCSEL 131. Suitable materials are chosen for this and the spectral transmission curves of mirrors, not shown in this figure, formed on the photodiode are adapted as required. The fact of having a transmitter, here a VCSEL 131, as second optoelectronic element 106, and a photodetector, here a photodiode 132, as first optoelectronic element 103, is not specific to this device and may apply to all of the embodiments of the present invention.

The present invention further concerns a method for producing a transmitting and receiving device 100, also subject of the present invention, which is intended to cooperate with an optical fibre 2.

The aim is firstly to solidarise a first optoelectronic element 103, here a VCSEL 131, with a pierced platform 101, equipped with at least one through hole 102. This hole 102 may for example be formed during a prior step in which the platform 101 is pierced to form the hole 102. The optical fibre 2 is introduced into this hole 102.

The VCSEL 131 used is similar to that described in the previous FIG. 5. The stacks 29, 30 of layers of different materials forming the Bragg mirrors 21, 22, as well as the active medium 20, are generally formed by vapour phase epitaxy, for example from organometallic compounds (MOCVD or organometallic chemical vapour deposition) or epitaxy by molecular jet of semi-conductor alloys, such as for example aluminium arsenide (AlAs) or gallium arsenide (GaAs). These techniques make it possible to adjust the deposition and the thickness of layers of semi-conductor material with a precision of around the inter atomic distance. The Bragg mirrors 20 and 21 may also be formed by less costly thin film deposition techniques, such as for example by evaporation or by sputtering, of dielectric materials, for example silicon dioxide (SiO₂), titanium dioxide (TiO₂) or even hafnium dioxide (HfO₂). Generally speaking, the space between the mirrors of a VCSEL is around 1 to 2 micrometers: it ensues that the modes of such a laser are well separated (very large free spectral interval).

The solidarisation of the VCSEL 131 with the platform 101 may for example be achieved by a hybridization of the first optoelectronic element 103 on the platform 101. To do this, a connection by microbeads 104 is going to be used. The microbeads 104 are therefore formed based on a fusible material on one face 114 of the first optoelectronic element 103, said face 114 being intended to be facing the optical fibre 2 when the first optoelectronic element 103 will be hybridized on the platform 101.

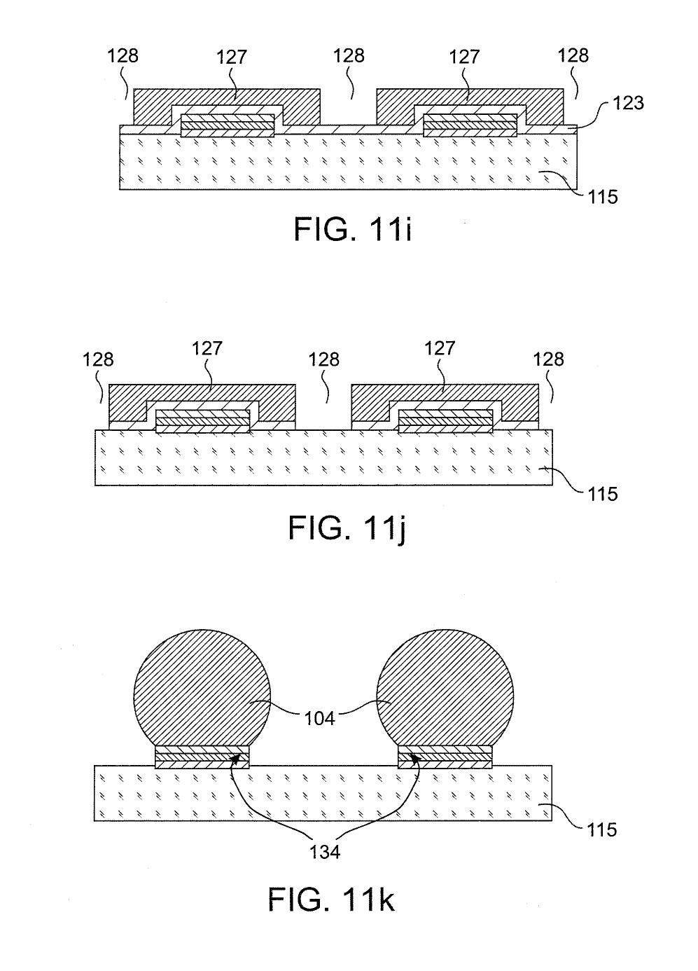

The different steps of manufacturing microbeads 104 on the first optoelectronic element 103 are illustrated in FIGS. 11a to 11k.

In these FIGS. 11a to 11k, only a substrate 115 of the first element 103 is shown, and only the manufacture of two microbeads 104 is shown. The step of FIG. 11a consists in depositing on the face 114 an anchoring metallization in a wettable material 119 for a fusible material that will compose the microbeads. The wettable material 119 may be composed for example of three thin films 116, 117 and 118 respectively of titanium, nickel and gold. In FIG. 11b, a layer of resin 120 is deposited and spread out on the wettable material 119. The step of FIG. 11c is an exposure of the layer of resin 120 so as to only leave resin sites 121, 122 corresponding to the future areas for receiving microbeads. At the step of FIG. 11d, the wettable material 119 that is not found underneath the emplacements 121, 122 is eliminated by etching, forming the metallic contacts 134. At the step of FIG. 11e, the resin sites 121, 122 are eliminated by dissolution with a solvent. At the step of FIG. 11f, a metallic base 123 is deposited on the metallic contacts 134 and on the parts of the substrate 115 that are laid bare next to the metallic contacts 134. This metallic base 123 may for example be achieved by cathodic sputtering. The nature of the material constituting the metallic base 123 depends on the fusible material that is going to be used for the microbeads. For example, if the fusible material used for the microbeads is an alloy composed of 60% tin and 40% lead, the metallic base 123 is also an alloy composed of 60% tin and 40% lead. At the step of FIG. 11g, the resin 124 is deposited between the metallic contacts 134 in order to delimit the zones 125, 126 into which will be introduced the fusible material of the microbeads. A fusible alloy 127 is deposited in the zones 125, 126 at the step of FIG. 11h. This fusible alloy 127 may for example be formed by electrolytic growth or by electrodeposition. At the step of FIG. 11i, the resin 124 is eliminated for example by dissolution with a solvent, thereby creating zones 128 in which the metallic base 123 is bare. The metallic base 123 thus laid bare in the zones 128 is eliminated at the step of FIG. 11j for example by etching. Finally, at the step of FIG. 11k, the substrate 115 is heated to attain a temperature greater than or equal to the melting temperature of the fusible material 127. While the fusible material 127 is in the liquid phase, surface tensions are going to cause the formation of microbeads 104. The shape and the size of the microbeads 104 depend on the quantity of fusible material 127 compared to the size of the metallic contacts 134. To produce microbeads 104 of different sizes, not shown in FIGS. 11a to 11k, each metallic contact 134 is formed so as to have dimensions proportional to the diameter of the microbead 104 that will be in contact with it. Similarly, the quantity of fusible material 127 introduced into each of the zones 125, 126 is proportional to the desired size of the microbeads 104.

The process for manufacturing the microbeads 108 on the second optoelectronic element 106 is similar to that disclosed previously for the microbeads 104.

Once the microbeads 104 have been manufactured, the solidarisation of the first optoelectronic element 103 with the platform 101 may be carried out by hybridization of the first optoelectronic element 103 on the platform 101. The hybridization of an element with self-alignment on the microbeads of fusible material has been developed and is generally used for the brazing of components with self-alignment. This type of hybridization uses the surface tension forces exercised by a drop of molten fusible material on the part to be fixed.

FIG. 12 represents different steps for the hybridization of the first element 103 on the platform 101. The hybridization of the second element 106 on the platform 101 would be similar. The step a) consists in pre-aligning the first optoelectronic element 103 on the metallic contacts 130 of the platform 101. Said metallic contacts 130 define the desired location of the first element 103 on the platform 101. At the step b), the microbeads 104 are heated, in such a way that they wet the metallic contacts 130. Finally, at the step c), surface tension forces are exercised by the microbeads 104 on the first element 103. Given that the molten fusible material of the microbeads 104 tends to minimise its contact surface with the exterior environment, this brings about a self-alignment of the first element 103 on the platform 101. The precisions thereby obtained may be sub-micronic depending on the number and the size of the microbeads 104.

Thus, the first optoelectronic element 103 ends up hybridized with precision facing the hole 102. The hybridization of the second optoelectronic element 106 on the platform 101 is then carried out in the same way as has been explained for the first optoelectronic element 103. In FIG. 12, the second optoelectronic element 106 is intended to be hybridized directly on the platform 101

The method, subject of the present invention, may comprise an additional step consisting in inserting between the first optoelectronic element 103 and the second optoelectronic element 106 a filter 109, as shown in FIG. 7A, or even arrange the filter 109 on one face 113 of the second optoelectronic element 106, as shown in FIG. 7B, when the first optoelectronic element 103 is a laser emitter and the second optoelectronic element 106 is a photodetector, to protect the photodetector from parasite laser beams that may be transmitted by the laser emitter in the direction of the photodetector.

Known generalities on the flip chip, V-groove techniques, V-hole techniques and passive alignment techniques are disclosed in the document “Optoelectronic packaging” of Mickelson A. R., Willey series 1997, as well as in the document “Microsystèmes optoélectroniques” of Viktorovitch P., Lavoisier-Hermes 2003.

Although several embodiments of the present invention have been described in a detailed manner, it will be understood that different changes and modifications may be made without going beyond the scope of the invention.

1-24. (canceled)

25. An optoelectronic transmitting and receiving device, comprising:
a pierced platform including at least one through hole for introduction of an optical fiber;
a first optoelectronic element integral with the platform, arranged substantially facing the through hole and configured to emit or receive a first laser beam at a first wavelength; and
at least one second optoelectronic element directly hybridized on the platform and arranged substantially facing the through hole, the first optoelectronic element being arranged between the platform and the second optoelectronic element, which is configured to receive or emit a second laser beam at a second wavelength, different than the first wavelength, passing through the first optoelectronic element.

26. An optoelectronic transmitting and receiving device according to claim 25, the first optoelectronic element being transparent or quasi-transparent to the second wavelength of the second laser beam received or emitted by the second optoelectronic element.

27. An optoelectronic transmitting and receiving device according to claim 25, the first or the second optoelectronic element being a laser emitter or a VCSEL.

28. An optoelectronic transmitting and receiving device according to claim 25, the first or the second optoelectronic element being a photodetector, or a photodiode.

29. An optoelectronic transmitting and receiving device according to claim 27, the VCSEL comprising a laser beam emission surface orientated facing the through hole and a microlens integrated on the emission surface.

30. An optoelectronic transmitting and receiving device according to claim 25, the first optoelectronic element being hybridized on the platform.

31. An optoelectronic transmitting and receiving device according to claim 30, hybridization of the first optoelectronic element on the platform being carried out with a connection by microbeads.

32. An optoelectronic transmitting and receiving device according to claim 31, the microbeads associated with the first optoelectronic element being based on a fusible material.

33. An optoelectronic transmitting and receiving device according to claim 32, the fusible material being an alloy based on gold and tin, tin and lead, or a pure or almost pure metal based on tin or indium.

34. An optoelectronic transmitting and receiving device according to claim 25, hybridization of the second optoelectronic element being carried out with a connection by microbeads.

35. An optoelectronic transmitting and receiving device according to claim 34, the microbeads associated with the second optoelectronic element being based on a fusible material.

36. An optoelectronic transmitting and receiving device according to claim 35, the fusible material being an alloy based on gold and tin, tin and lead, or a pure or almost pure metal based on tin or indium.

37. An optoelectronic transmitting and receiving device according to claim 34, all of the microbeads associated with the second optoelectronic element having substantially a same diameter.

38. An optoelectronic transmitting and receiving device according to claim 34, the microbeads associated with the second optoelectronic element not all having substantially a same diameter.

39. An optoelectronic transmitting and receiving device according to claim 25, further comprising a filter inserted between the first and the second optoelectronic element.

40. An optoelectronic transmitting and receiving device according to claim 39, the filter being arranged on one face of the second optoelectronic element that is located next to the first optoelectronic element.

41. An optoelectronic transmitting and receiving device according to claim 25, the platform being based on silicon.

42. A method for forming a transmitting and receiving device, comprising:
a) solidarization of a first optoelectronic element with a pierced platform including at least one through hole for introduction of an optical fiber, the first optoelectronic element being arranged substantially facing the through hole;
b) solidarization of a second optoelectronic element with the platform, the second optoelectronic element comprising one face arranged substantially facing the through hole, carried out according to:
formation of microbeads based on a fusible material on the face of the second optoelectronic element, the face configured to be on the side of the through hole,
hybridization of the second optoelectronic element on the platform by the microbeads,
the first optoelectronic element being arranged between the platform and the second optoelectronic element.

43. A method according to claim 42, further comprising, before the solidarization a), piercing the platform, thereby forming the through hole.

44. A method according to claim 42, the a) solidarization of the first optoelectronic element with the platform being carried out according to:
formation of microbeads based on a fusible material on one face of the first optoelectronic element, the face configured to face the through hole,
hybridization of the first optoelectronic element on the platform by microbeads.

45. A method according to claim 42, further comprising inserting a filter between the first optoelectronic element and the second optoelectronic element.

46. A method according to claim 42, further comprising arranging a filter on the face of the second optoelectronic element.
